(19) United States
(12) Patent Application Publication
(10) Pub. No.: US 2026/0025150 A1
(43) Pub. Date: Jan. 22, 2026

(54) SEMICONDUCTOR DEVICE AND COMMUNICATION SYSTEM

(71) Applicant: ROHM CO., LTD., Kyoto (JP)

(72) Inventor: Kei NAGAO, Kyoto (JP)

(21) Appl. No.: 19/263,126

(22) Filed: Jul. 8, 2025

(30) Foreign Application Priority Data
Jul. 17, 2024 (JP) 2024-114144

(51) Int. Cl. H03M 13/09

(52) U.S. Cl. CPC H03M 13/098; H03M 13/093

(57) ABSTRACT

A semiconductor device comprises a receiving section configured to receive reception data as serial data from an outside, a frame counter configured to count up a count value when it is determined that there is no anomaly based on the reception data, a register, and a transmitting section configured to transmit a first response data, including the count value from the frame counter read from the register, to an outside when Write/Read information included in the reception data indicates Write.

### TECHNICAL FIELD

The present disclosure relates to a semiconductor device.

### BACKGROUND

Semiconductor devices comprising serial communication functions are used in various applications.

Furthermore, an example of circuit technology related to serial communication is disclosed in Patent Document 1.

### PRIOR ART DOCUMENT

### Patent Document

[Patent document 1] Japan Patent Publication No. 2017-224946.

### BRIEF DESCRIPTION OF THE DRAWINGS

FIG. 1 is a diagram showing a configuration of a communication system according to an exemplary embodiment of the present disclosure.

FIG. 2 is a diagram showing a configuration related to communication control in a semiconductor device.

FIG. 3 is a diagram showing an example of reception data and transmission data in a Write process.

FIG. 4 is a diagram showing an example of reception data and transmission data in a Write process.

FIG. 5 is a diagram showing a configuration example of response data including an anomalous state.

FIG. 6 is a diagram showing an example of reception data and transmission data in a Write process.

FIG. 7 is a diagram showing an example of reception data and transmission data in a Write process.

FIG. 8A is a diagram showing a watchdog timer in a timeout mode.

FIG. 8B is a diagram showing a watchdog timer in a window mode.

FIG. 9 is an external view showing an example of a vehicle.

### DETAILED DESCRIPTION OF THE EMBODIMENTS

Hereinafter, exemplary embodiments of the present disclosure are illustrated with reference to figures.

### 1. COMMUNICATION SYSTEM

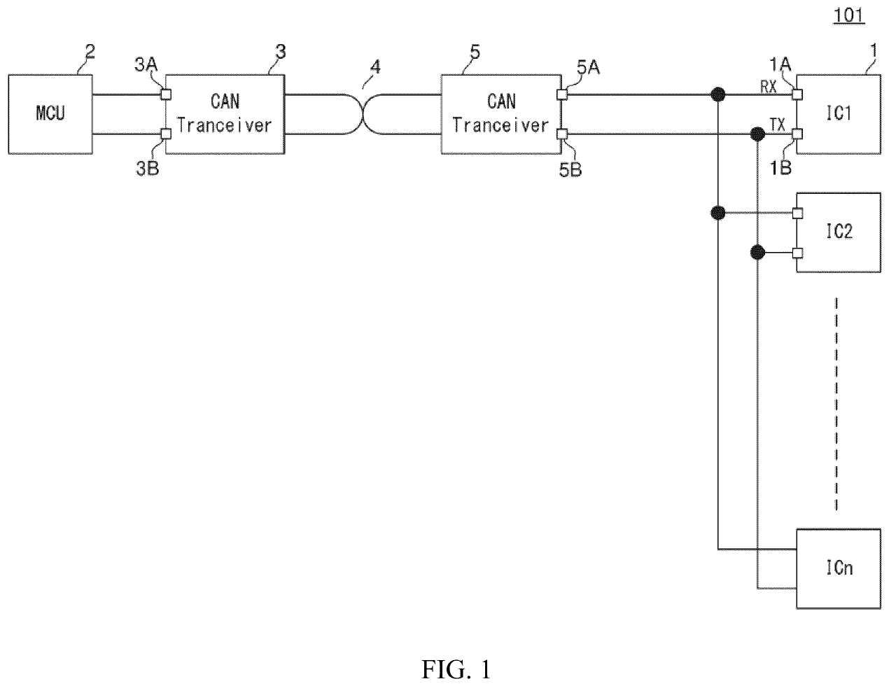

FIG. 1 is a diagram showing a configuration of a communication system 101 according to an exemplary embodiment of the present disclosure. The communication system 101 comprises n (n is an integer of 2 or more) semiconductor devices 1, an MCU 2, a CAN (Controller Area Network) transceiver 3, a CAN bus 4, and a CAN transceiver 5. The communication system 101 is, as an example, for in-vehicle use. Furthermore, the semiconductor device 1 may be singular.

Between the MCU 2 and the CAN transceiver 3, communication is conducted using UART (Universal Asynchronous Receiver/Transmitter). UART is a protocol for exchanging serial data between two devices. In UART, bidirectional communication is conducted over two lines between a transmitting side and a receiving side.

Communication between the CAN transceivers 3, 5 is conducted via the CAN bus 4. CAN is a serial communication standard standardized by international standards such as ISO 11898. In CAN, a differential voltage method is used to transmit data based on a level of a voltage difference generated between two communication lines.

The CAN transceiver 3 comprises a TXD (transmit data input) terminal 3A and an RXD (receive data output) terminal 3B. The CAN transceiver 3 outputs data input to the TXD terminal 3A to the CAN bus 4 and outputs data input from the CAN bus 4 from the RXD terminal 3B.

The CAN transceiver 5 comprises an RXD terminal 5A and a TXD terminal 5B. The CAN transceiver 5 outputs data input to the TXD terminal 5B to the CAN bus 4 and outputs data input from the CAN bus 4 from the RXD terminal 5A.

The semiconductor device 1 is an IC (integrated circuit) in which circuits with predetermined functions are integrated, and is configured, for example, as an LED (light-emitting diode) driver IC. Furthermore, the n semiconductor devices 1 do not necessarily all have the same function.

The semiconductor device 1 comprises an RX (receive data input) terminal 1A and a TX (transmit data output) terminal 1B. The n RX terminals 1A are commonly connected to the RXD terminal 5A. The n TX terminals 1B are commonly connected to the TXD terminal 5B.

Since the n semiconductor devices 1 correspond to the same protocol, the n semiconductor devices 1 can be commonly connected to the same CAN transceiver 5. A reception data RX output from the RXD terminal 5A is input to the n RX terminals 1A. The reception data RX specifies a device address of one of the n semiconductor devices 1. Additionally, a transmission data TX output from the TX terminal 1B is input to the TXD terminal 5B.

### 2. SEMICONDUCTOR DEVICE

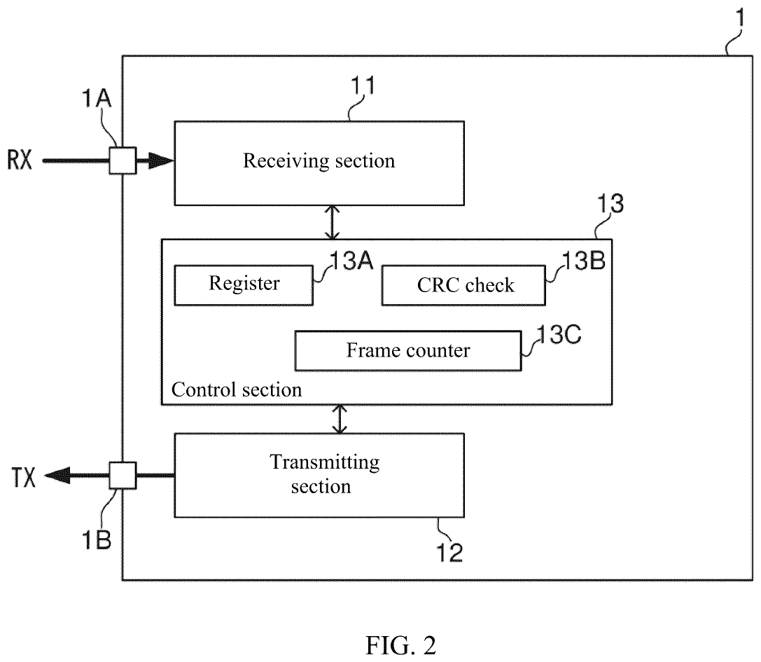

FIG. 2 is a diagram showing a configuration related to communication control in the semiconductor device 1. Furthermore, in FIG. 2, configurations other than those related to communication control are omitted; for example, if the semiconductor device 1 is an LED driver IC, the semiconductor device 1 comprises configurations related to LED driving, etc.

The semiconductor device 1 comprises a receiving section 11, a transmitting section 12, and a control section 13. The receiving section 11 receives the reception data RX via the RX terminal 1A and performs reception processing.

The control section 13 comprises a register 13A and a CRC (Cyclic Redundancy Check) check section 13B. The CRC check section 13B performs an error detection using a CRC data included in the reception data RX. The register 13A can store various data, and data can be written to the register 13A, or data can be read from the register 13A.

The transmitting section 12 transmits the transmission data TX via the TX terminal 1B. Furthermore, a frame counter 13C included in the control section 13 is described below.

### 3. CONFIGURATION OF RECEPTION DATA

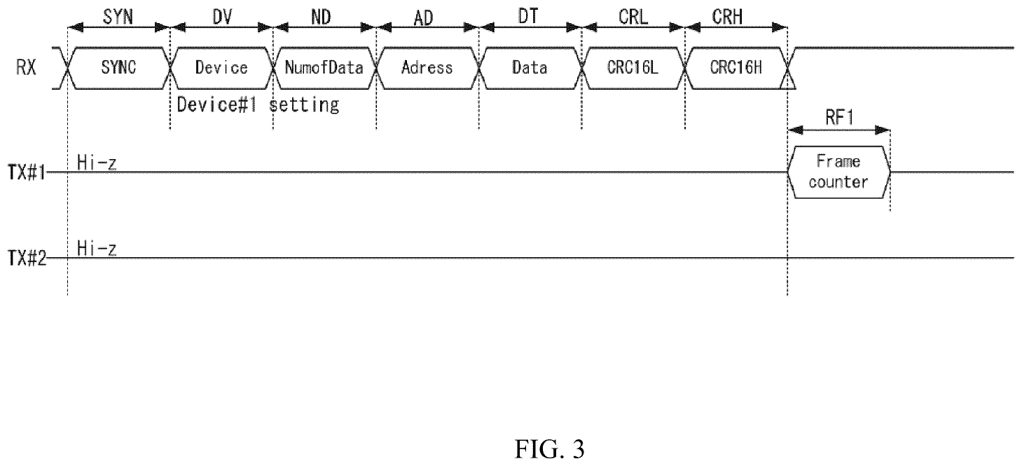

Herein, a data configuration of the reception data RX is illustrated using FIG. 3. Furthermore, FIG. 3 is a timing chart showing an example of a Write process described below.

In UART, communication is conducted using data units called frames. A frame comprises bit data from a start bit to a stop bit. The start bit is at a low level, and the stop bit is at a high level. Between the start bit and the stop bit, bit data of a predetermined number of bits are arranged. Herein, as an example, the above predetermined number of bits is set to 8 bits, and one frame comprises 10 bits of bit data.

As shown in FIG. 3, the reception data RX sequentially comprises a synchronization frame SYN, a device frame DV, a data number frame ND, a register address frame AD, a data frame DT, and CRC frames CRL, CRH from the beginning. Furthermore, a 16-bit CRC data is divided into two frames, CRL (lower 8 bits) and CRH (higher 8 bits).

The synchronization frame SYN is a bit data used to set a baud rate (unit: bps) for the semiconductor device 1. Sampling of each frame following the synchronization frame SYN is performed according to the set baud rate, and a bit value (0 or 1) of each bit is obtained.

The device frame DV includes a device address, a Read/Write bit, etc. The device address is a bit data indicating an address of a target device (semiconductor device 1). The Read/Write bit is a bit data indicating either Read or Write. Read indicates data reading from the semiconductor device 1, and Write indicates data writing to the semiconductor device 1.

The data number frame ND is a bit data indicating a number of data frames DT. Furthermore, in FIG. 3, as an example, the number of data frames DT is 1, but it may be 2 or more.

The register address frame AD is a bit data indicating an address in the register 13A. The data frame DT is a bit data indicating a data to be written. The CRC frames CRL, CRH are bit data indicating error detection codes added to the data frame DT.

### 4. WRITE PROCESS

Next, the Write process is illustrated using FIG. 3. Furthermore, for convenience, it is assumed that for n semiconductor devices 1, n=2.

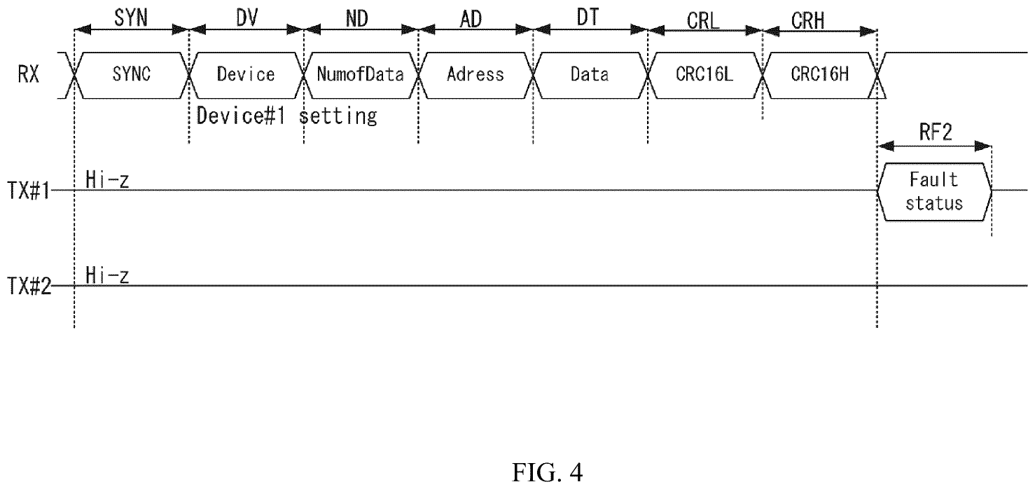

As shown in FIG. 3, as an example, a device address in the device frame DV of the reception data RX indicates a device #1 among the two semiconductor devices 1. That is, the device #1 is the target device. Furthermore, the same applies to FIGS. 4, 6, and 7, which are described below.

In a case of FIG. 3, during a period when the reception data RX is being received, the transmission data TX (TX #1, TX #2) output from TX terminals 1B of both device #1 and device #2 are in a high-impedance state (Hi-z). Then, since in the received reception data RX, the Read/Write bit=Write, the control section 13 in the semiconductor device 1, which is the device #1, recognizes that it is a Write process.

Then, once the CRC frames CRL, CRH are received by the receiving section 11, the CRC check section 13B performs a CRC check on a Write data included in the data frame DT using the CRC data included in the CRC frames CRL, CRH. If no anomalies are found as a result of the CRC check, the control section 13 writes the Write data to an address in the register 13A indicated by the register address frame AD. At this time, the frame counter 13C increments the count value. On the other hand, if an anomaly is detected by the CRC check, the frame counter 13C does not increment the count value. The count value by the frame counter 13C is stored in register 13A.

By providing a frame counter in this way, a safety mechanism for a communication bus specified in ISO 26262 regarding a functional safety of in-vehicle equipment can be provided.

Furthermore, as described above, even when the device frame DV indicates the device itself (semiconductor device 1), count control by the frame counter 13C may be performed, but regardless of the device address indicated by the device frame DV, a CRC check may be performed each time the reception data RX is received, and count control by the frame counter 13C may be performed. That is, even when the device #1 receives the reception data RX targeting the device #2 (a device different from itself), the count control by the frame counter 13C may be performed.

Additionally, the count value by the frame counter 13C may be set to automatically repeat by counting up from a minimum value to a maximum value and then returning to the minimum value again. For example, if the count value is 8 bits, it may be set as 0→1→ . . . →254→255→0→1. . . .

### 5. COUNT VALUE RESPONSE

Additionally, in this embodiment, as shown in FIG. 3, in the case of a Write process, after the reception data RX is received up to the CRC frames CRL, CRH, the transmitting section 12 transmits the count value from the frame counter 13C read from the register 13A as a response frame RF1 by the transmission data TX. The response frame RF1 transmitted from the device #1 is transmitted to the MCU 2 via the CAN transceiver 5, the CAN bus 4, and the CAN transceiver 3. As a result, the MCU 2 can obtain the count value of the device #1.

As such, according to this embodiment, even without reading the count value from the register 13A by transmitting a Read command with the Read/Write bit in the reception data RX set to Read from the MCU 2, it is possible to respond with the count value every time a Write process is performed. Since the Write command is more frequent than the Read command, the count value can be communicated to the MCU 2 at a higher frequency.

### 6. RESPONSE TO ANOMALOUS STATE

In this embodiment, not only the count value from the frame counter 13C as described above but also an anomalous state in the semiconductor device 1 can be made to be responded. FIG. 4 is a diagram showing the Write process corresponding to FIG. 3; however, after the CRC frames CRL, CRH are received, a response frame RF2 including the anomalous state read from the register 13A is transmitted as the transmission data TX by the transmitting section 12.

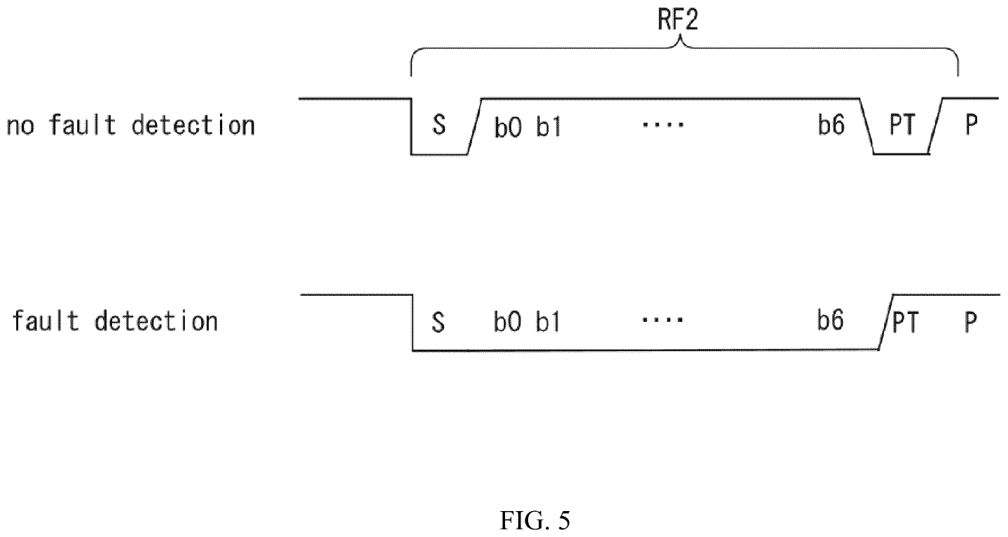

FIG. 5 is a diagram showing a configuration example of the response frame RF2. An upper part of FIG. 5 shows a case where no anomalous state is detected, and a lower part of FIG. 5 shows a case where an anomalous state is detected. The response frame RF2 includes a start bit S, a stop bit P, and 8-bit data between the start bit S and the stop bit P. The 8-bit data described above includes 7 bits (b0 to b6) anomalous bit data and a parity bit PT added to the anomalous bit data. When no anomalous state is detected, the anomalous bit data is at a high level, and when an anomalous state is detected, the anomalous bit data is at a low level. The anomalous bit data is at a constant level across 7 bits.

Furthermore, in this embodiment, each time a Write command is received via the reception data RX, either a response frame RF1 indicating the count value or a response frame RF2 indicating the anomalous state is responded. For example, the response frame RF1 may be responded once every few times. For example, if RF1 is responded once every four times, it would be RF2→RF2→RF2→RF1→RF2→ . . . .

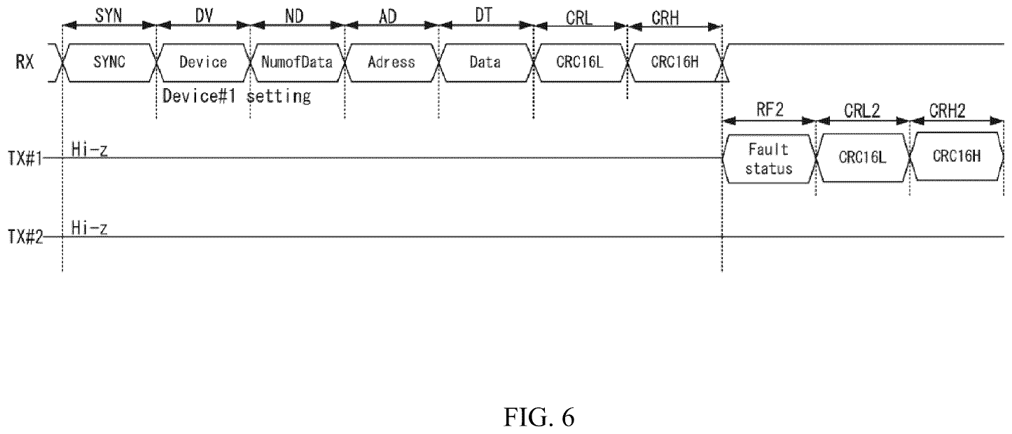

Additionally, as shown in FIG. 6, CRC frames CRL2, CRH2 may be added to the response frame RF2 indicating the anomalous state and responded. In this case, in the response frame RF2, for example, each of the 8-bit anomalous bit data between the start bit S and the stop bit P may be arranged so that each bit indicates a different type of anomalous state.

### 7. WATCHDOG TIMER

Additionally, in this embodiment, the semiconductor device 1 may comprise a watchdog timer function. As a result, a safety mechanism related to program sequence monitoring as specified in ISO 26262 can be provided.

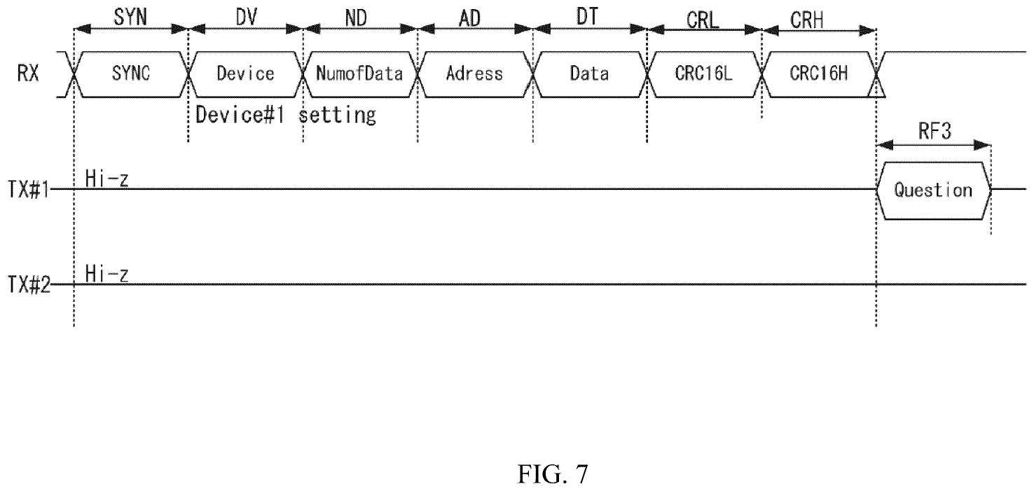

The semiconductor device 1 can be provided with a watchdog timer in a Q&A mode. In this case, FIG. 7 shows a Write process corresponding to FIG. 3; after receiving the CRC frames CRL, CRH, a response frame RF3 including a Question is transmitted as a transmission data TX via the transmitting section 12. The Question is a random data (e.g., 8 bits). When the response frame RF3 is transmitted to the MCU 2, the MCU 2 transmits a data frame DT including an Answer to the semiconductor device 1 as a Write process by including it in a reception data RX. The control section 13 in the semiconductor device 1 determines that there is no anomaly if the received Answer is the expected data, and determines that there is an anomaly if the received Answer is not the expected data.

As such, since a Question is returned in response to the Write command, the MCU 2 can obtain the Question even without reading the Question from the register 13A by the Read command. Additionally, for each Write command, it is possible to respond with either a response frame RF1 indicating the count value, a response frame RF2 indicating the anomalous state, or a response frame RF3 indicating the Question. For example, it is possible to respond in the sequence of anomalous state→count value→Question→ . . . . As such, by combining the frame counter and the watchdog timer in this way, a diagnostic coverage of communication bus in ISO 26262 can be made “high.”

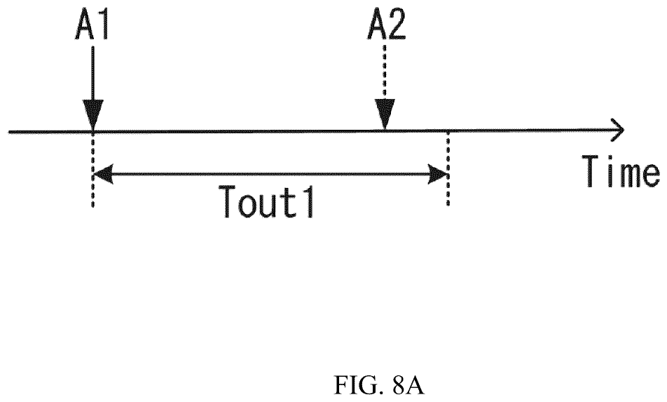

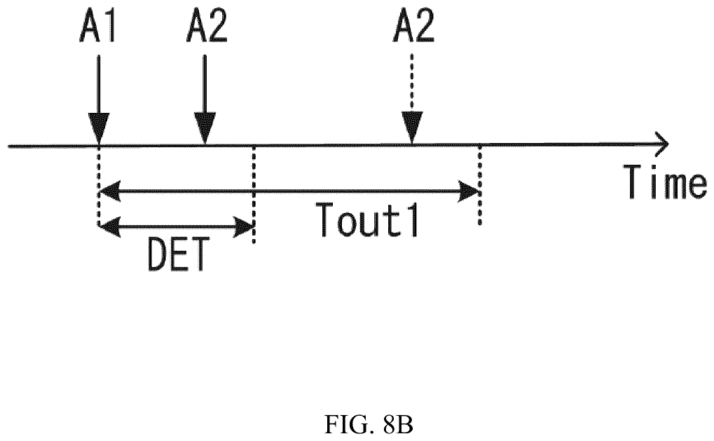

Additionally, a watchdog timer in a timeout mode related to the Answer may be provided. In this case, as shown in FIG. 8A, if the control section 13 does not receive a next Answer A2 within a predetermined timeout period Tout1 after receiving an Answer A1, it is determined that there is an anomaly.

Additionally, a watchdog timer in a window mode related to the Answer may be provided. In this case, as shown in FIG. 8B, if the control section 13 does not receive the next Answer A2 within a predetermined timeout period Tout1 after receiving an Answer A1, or if it receives the next Answer A2 within a predetermined detection time DET (shorter than Tout1) after receiving Answer A1, it is determined that there is an anomaly.

### 8. VEHICLE

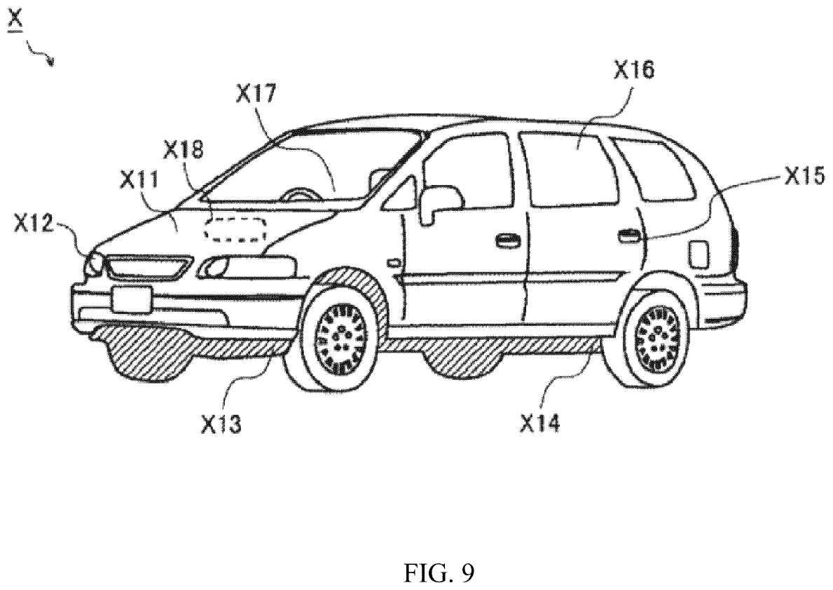

FIG. 9 is an external view showing an example configuration of a vehicle X. The vehicle X of this configuration example is equipped with various electronic equipment X11 to X18 that operate by receiving power supply from an unillustrated battery. Furthermore, the mounting positions of the electronic equipment X11 to X18 in FIG. 9 may differ from actual positions for convenience of illustration.

The electronic equipment X11 is an engine control unit that performs control related to the engine (injection control, electronic throttle control, idling control, oxygen sensor heater control, auto cruise control, etc.).

The electronic equipment X12 is a lamp control unit that performs control of turning on and off lights of HID [high intensity discharged lamp], DRL [daytime running lamp], etc.

The electronic equipment X13 is a transmission control unit that performs control related to a transmission.

The electronic equipment X14 is a body control unit that performs control related to a movement of the vehicle X (ABS [anti-lock brake system] control, EPS [electric power steering] control, electronic suspension control, etc.).

The electronic equipment X15 is a security control unit that performs drive control of door locks, security alarms, etc.

The electronic equipment X16 is electronic equipment that is installed in the vehicle X at a time of shipment from a factory as standard equipment or manufacturer option, such as wipers, electric door mirrors, power windows, dampers (shock absorbers), electric sunroofs, electric seats, etc.

The electronic equipment X17 is electronic equipment that is arbitrarily installed in the vehicle X as user options, such as in-vehicle A/V [audio/visual] equipment, a car navigation system, an ETC [electronic toll collection system], etc.

The electronic equipment X18 is electronic equipment that comprises a high-voltage motor, such as an in-vehicle blower, an oil pump, a water pump, a battery cooling fan, etc.

Furthermore, a communication system 101 including the aforementioned MCU 2 and semiconductor device 1 can be applied to any of the electronic equipment X11 to X18.

### 9. OTHER

Furthermore, in addition to the above embodiments, the various technical features disclosed in this specification can be modified in various ways without departing from the spirit of the technical creation. That is, the above embodiments should be considered in all respects as illustrative and not restrictive, and the technical scope of the present disclosure should not be limited to the above embodiments but should be understood to include all modifications that fall within the meaning and scope of the claims and equivalents.

### 10. APPENDIX

As described above, a semiconductor device (1) according to one aspect of the present disclosure is configured that the semiconductor device comprises:
a receiving section (11) configured to receive reception data (RX) as serial data from an outside;
a frame counter (13C) configured to count up a count value when it is determined that there is no anomaly based on the reception data;
a register (13A); and
a transmitting section (12) configured to transmit a first response data (RF1) including the count value from the frame counter read from the register, to an outside when Write/Read information included in the reception data indicates Write (first configuration).

According to such configuration, a configuration that can effectively detect anomalies in a communication bus can be realized.

Furthermore, the first configuration described above may be configured so that the frame counter counts up the count value when device address data included in the reception data indicates the semiconductor device itself (second configuration).

Furthermore, the first configuration described above may be configured so that the frame counter counts up the count value regardless of a device indicated by device address data included in the reception data (third configuration).

Furthermore, any one of the first to third configurations described above may be configured so that the transmitting section transmits either the first response data or another response data each time the reception data is received when the Write/Read information indicates Write (fourth configuration).

Furthermore, the fourth configuration described above may be configured so that the first response data is transmitted less frequently than the another response data (fifth configuration).

Furthermore, the fourth or fifth configuration described above may be configured so that the another response data is a second response data (RF2) that includes an anomalous state of the semiconductor device (sixth configuration).

Furthermore, the sixth configuration described above may be configured so that the second response data includes a start bit(S), a stop bit (P), and bit data between the start bit and the stop bit, and the bit data includes data that is at a constant level across multiple bits (b0 to b6) depending on whether there is an anomaly, and a parity bit (PT) (seventh configuration).

Furthermore, the sixth or seventh configuration described above may be configured so that the second response data is transmitted with a CRC check data (CRL2, CRH2) added thereto (eighth configuration).

Furthermore, any one of the fourth to eighth configurations described above may be configured so that the another response data is a third response data (RF3) that includes a Question in a watchdog timer in a Q&A mode (ninth configuration).

Furthermore, the ninth configuration described above may be configured so that the semiconductor device comprises a determination section (13) that determines that there is an anomaly if there is no next Answer within a predetermined timeout time (Tout1) after an Answer to the Question (tenth configuration).

Furthermore, the tenth configuration described above may be configured so that the determination section also determines that there is an anomaly if there is a next Answer within a predetermined detection time (DET) shorter than the timeout time after an Answer to the Question (eleventh configuration).

Furthermore, any one of the first to eleventh configurations described above may be configured so that the count value counts up from a minimum value and returns to the minimum value when it reaches a maximum value (twelfth configuration).

Furthermore, one aspect of the present disclosure is a communication system (101) comprising:
the semiconductor device of any one of the first to twelfth configurations described above; and
a transmitting device (20) configured to transmit the reception data and receive the first response data (thirteenth configuration).

Furthermore, the thirteenth configuration may be configured for in-vehicle use (fourteenth configuration).

### INDUSTRIAL APPLICABILITY

The present disclosure can be utilized, for example, in communication systems for various applications.

1. A semiconductor device, comprising:
a receiving section configured to receive reception data as serial data from an outside;
a frame counter configured to count up a count value when it is determined that there is no anomaly based on the reception data;
a register; and
a transmitting section configured to transmit a first response data, including the count value from the frame counter read from the register, to an outside when Write/Read information included in the reception data indicates Write.

2. The semiconductor device of claim 1, wherein the frame counter counts up the count value when device address data included in the reception data indicates the semiconductor device itself.

3. The semiconductor device of claim 1, wherein the frame counter counts up the count value regardless of a device indicated by device address data included in the reception data.

4. The semiconductor device of claim 1, wherein the transmitting section transmits either the first response data or another response data each time the reception data is received when the Write/Read information indicates Write.

5. The semiconductor device of claim 4, wherein the first response data is transmitted less frequently than the another response data.

6. The semiconductor device of claim 4, wherein the another response data is a second response data that includes an anomalous state of the semiconductor device.

7. The semiconductor device of claim 6, wherein the second response data includes a start bit, a stop bit, and bit data between the start bit and the stop bit, and
the bit data includes data that is at a constant level across multiple bits depending on whether there is an anomaly, and a parity bit.

8. The semiconductor device of claim 6, wherein the second response data is transmitted with a CRC check data added thereto.

9. The semiconductor device of claim 4, wherein the another response data is a third response data that includes a Question in a watchdog timer in a Q&A mode.

10. The semiconductor device of claim 9, comprising a determination section that determines that there is an anomaly if there is no next Answer within a predetermined timeout time after an Answer to the Question.

11. The semiconductor device of claim 10, wherein the determination section also determines that there is an anomaly if there is a next Answer within a predetermined detection time shorter than the timeout time after an Answer to the Question.

12. The semiconductor device of claim 1, wherein the count value counts up from a minimum value and returns to the minimum value when it reaches a maximum value.

13. A communication system, comprising:
the semiconductor device of claim 1; and
a transmitting device configured to transmit the reception data and receive the first response data.

14. The communication system of claim 13, wherein it is for in-vehicle use.
